(19) United States
(12) Patent Application Publication
(10) Pub. No.: US 2016/0153845 A1
(43) Pub. Date: Jun. 2, 2016

(54) PRESSING SENSOR AND METHOD FOR MANUFACTURING PRESSING SENSOR

(71) Applicant: Murata Manufacturing Co., Ltd., Nagaokakyo-shi (JP)

(72) Inventor: Hideki Kawamura, Nagaokakyo-shi (JP)

(21) Appl. No.: 15/007,435

(22) Filed: Jan. 27, 2016

Related U.S. Application Data
(63) Continuation of application No. PCT/JP2014/074350, filed on Sep. 16, 2014.

(30) Foreign Application Priority Data
Sep. 17, 2013 (JP) 2013-191304

(51) Int. Cl. G01L 1/16; H01L 41/047; H01L 41/25; H01L 41/113; H01L 41/193

(52) U.S. Cl. CPC G01L 1/16; H01L 41/1132; H01L 41/193; H01L 41/25; H01L 41/047

(57) ABSTRACT

A pressing sensor that includes a piezoelectric polymer film having a top principal surface and a back principal surface opposed to each other, and whose piezoelectric polymer is oriented along the top principal surface and the back principal surface; a first detection electrode disposed opposite the top principal surface of the piezoelectric polymer film; and a second detection electrode disposed opposite the back principal surface of the piezoelectric polymer film and opposing the first detection electrode. A first shape of the piezoelectric polymer film as viewed from the top principal surface and a second shape of the piezoelectric polymer film as viewed from the back principal surface differ from each other.

### CROSS REFERENCE TO RELATED APPLICATIONS

The present application is a continuation of International application No. PCT/JP2014/074350, filed Sep. 16, 2014, which claims priority to Japanese Patent Application No. 2013-191304, filed Sep. 17, 2013, the entire contents of each of which are incorporated herein by reference.

### FIELD OF THE INVENTION

The present invention relates to a pressing sensor which detects a press on an operation surface such as a touch panel, and a pressing sensor manufacturing method.

### BACKGROUND OF THE INVENTION

An input device such as a touch panel not only detects an operation position on an operation surface but also detects a press amount on the operation surface in some cases, and additionally includes the pressing sensor which can detect the press amount on the operation surface. There are various configurations of pressing sensors having been developed, including a pressing sensor which uses a piezoelectric polymer film having good translucency and flexibility (see, for example, Patent Literature 1). The piezoelectric polymer film whose main material is polyvinylidene difluoride (PVDF) is typically known. Further, piezoelectric polymer films whose main materials are chiral polymers such as poly-L-lactic acid (PLLA) and poly-D-lactic acid (PDLA) are also known.

The piezoelectric polymer film whose main material is PVDF is rendered piezoelectric for detecting a pressing force in a film thickness direction by orienting the PFDF in a direction parallel to a film surface and poling the PVDF in the film thickness direction. Hence, by providing detection electrodes on top and back principal surfaces of the piezoelectric polymer films in a pressing sensor which uses the piezoelectric polymer film whose main material is PVDF, it is possible to obtain a voltage output corresponding to a pressing force in a film thickness direction.

Further, a piezoelectric polymer film whose main material is a chiral polymer such as PLLA and PDLA is rendered piezoelectric for detecting a pressing force in a film thickness direction by orienting the chiral polymer in a direction parallel to a film surface and cutting the film to define an outer shape size at a predetermined angle with respect to this direction. Hence, by providing detection electrodes on top and back principal surfaces of the piezoelectric polymer films, a pressing sensor which uses the piezoelectric polymer film whose main material is a chiral polymer can also provide a voltage output corresponding to a pressing force in a film thickness direction.

PTL 1: International Publication No. 2012/137897

### SUMMARY OF THE INVENTION

The above piezoelectric polymer film limits a direction in which the piezoelectricity is exhibited, according to a direction in which piezoelectric polymers such as PLLA are oriented or a poling direction. Further, the polarity of a voltage output of the pressing sensor depends on directions of top and back principal surfaces of the piezoelectric polymer film determined when the piezoelectric polymer film is assembled in a pressing sensor.

Hence, in a process of manufacturing the pressing sensor, it is necessary to correctly adjust directions of top and back principal surfaces of a piezoelectric polymer film when the piezoelectric polymer film is assembled. However, the top and back principal surfaces of the piezoelectric polymer film are difficult to distinguish in a case where electrode shapes disposed on top and back principal surfaces of a piezoelectric polymer film have the same shape, a case where electrodes disposed on the top and back principal surfaces of the piezoelectric polymer film are transparent, or a case where a piezoelectric polymer film is sandwiched by films which are different from the piezoelectric polymer film and are provided with electrodes. Thus, the top and back principal surfaces of the piezoelectric polymer film can be erroneously assembled.

It is therefore an object of the present invention to provide a pressing sensor structure and a pressing sensor manufacturing method which can increase accuracy in correctly assembling a piezoelectric polymer film in the pressing sensor.

The present invention relates to a pressing sensor which includes a piezoelectric polymer film which includes a top principal surface and a back principal surface opposite to each other, and whose piezoelectric polymer is oriented along the top principal surface and the back principal surface. A first detection electrode is disposed opposite the top principal surface of the piezoelectric polymer film, and a second detection electrode is disposed opposite the back principal surface of the piezoelectric polymer film and opposite to the first detection electrode. A first shape of the piezoelectric polymer film as viewed from the top principal surface and a second shape of the piezoelectric polymer film as viewed from the back principal surface differ from each other.

According to this configuration, since the shapes of the piezoelectric polymer film differ between the top principal surface and the back principal surface, it is possible to accurately distinguish between the top and back principal surfaces of the piezoelectric polymer film based on the shape of the piezoelectric polymer film. Consequently, it is possible to increase accuracy in correctly assembling the piezoelectric polymer film in the pressing sensor. Thus, it is possible to precisely manufacture the pressing sensor which can provide a detected voltage of a correct voltage polarity which reflects a direction of the pressing force working on the piezoelectric polymer film.

On the piezoelectric polymer film, a deformed portion having one of a cutaway shape, a projection shape and an opening shape exposed on the top principal surface and the back principal surface may be formed.

Preferably, the top principal surface and the back principal surface of the piezoelectric polymer film each include two long sides which are parallel to each other, and two short sides which are orthogonal to the two long sides, and the deformed portion is an angular portion connecting one of the two long sides to one of the two short sides. Alternatively, preferably, the top principal surface and the back principal surface of the piezoelectric polymer film each include four sides which are orthogonal to each other, and the deformed portion is formed on one of the four sides and offset from a center of the side. Alternatively, preferably, a shape of the deformed portion seen from the top principal surface of the piezoelectric polymer film and a shape of the deformed portion seen from the back principal surface of the piezoelectric polymer film differ from each other.

According to these configurations, it is possible to distinguish between the top and back principal surfaces of the piezoelectric polymer film based on a position and a shape of the deformed portion. Consequently, it is possible to easily prevent (suppress) that the top and back principal surfaces of the piezoelectric polymer film are upside down based on the position and the shape of the deformed portion when the piezoelectric polymer film is assembled in the pressing sensor, and increase accuracy in correctly assembling the piezoelectric polymer film in the pressing sensor.

In addition, according to these configurations, it is possible to easily distinguish a direction in which piezoelectric polymers of the piezoelectric polymer film are oriented, based on the position or the shape of the deformed portion. Consequently, it is possible to easily prevent (suppress) that an orientation direction of molecules of the piezoelectric polymer film is misaligned from an assembly reference direction when the piezoelectric polymer film is assembled in the pressing sensor, and increase accuracy in correctly assembling the piezoelectric polymer film in the pressing sensor.

Preferably, the top principal surface and the back principal surface of the piezoelectric polymer film each include four sides which are orthogonal to each other, and a main material of the piezoelectric polymer film is a chiral polymer which is oriented in a direction to intersect each of the four sides of the top principal surface and the back principal surface. Particularly, the chiral polymer is preferably oriented in a direction of approximately 45° with respect to each of the four sides of the top principal surface and the back principal surface of the piezoelectric polymer film.

According to this configuration, the piezoelectric polymer film whose main material is a chiral polymer includes piezoelectric tensor components (expressed as d₁₄ when a film thickness direction is a first axis and a film stretching direction is a third axis) for detecting a pressing force in the film thickness direction, and does not have pyroelectricity. Consequently, it is possible to obtain a voltage output without being influenced by a temperature change at a detection position.

Further, when the piezoelectric polymer film including the piezoelectric tensor components d₁₄ is attached to a glass plate or a resin plate and used, and when a molecular orientation direction is parallel to each side of the top and back principal surfaces (preferably a direction of 0°), a detected voltage corresponding to a pressing force of twisting the plate is outputted, but it is not possible to obtain the detected voltage corresponding to the pressing force of bending the plate. However, according to this configuration, the molecular orientation direction of the piezoelectric polymer film is a direction (preferably a direction of approximately 45°) to intersect each side of the top and back principal surfaces. Consequently, there is little influence of the pressing force of twisting the plate, and it is possible to obtain the detected voltage of a voltage value corresponding to a magnitude of the pressing force of bending the plate. In this regard, when the piezoelectric polymer film is to be attached to the plate at 0°, a direction of ±0° does not change even if the top and back principal surfaces are upside down and there is no problem. However, when the piezoelectric polymer film is to be attached to the plate at 45°, the piezoelectric polymer film is attached to the plate at −45° if the top and back principal surfaces are upside down, and output electric charges are inverted. It is necessary to attach the piezoelectric polymer film carefully so as not to erroneously attach the top and back principal surfaces upside down.

Preferably, the pressing sensor further includes a substrate which includes a surface on which the first detection electrode is formed, and includes a first electrode formation portion which covers the top principal surface of the piezoelectric polymer film, and a substrate which includes a surface on which the second detection electrode is formed, and includes a second electrode formation portion which covers the back principal surface of the piezoelectric polymer film.

According to this configuration, the first detection electrode and the second detection electrode are formed on the substrate including the first electrode formation portion and the second electrode formation portion, and the first electrode formation portion and the second electrode formation portion sandwich the piezoelectric polymer film. Consequently, it is possible to easily form the pressing sensor even in case of a combination of materials which make it difficult to directly form the first detection electrode and the second detection electrode on the surface of the piezoelectric polymer film. In addition, it is preferable to dispose an adhesive material for fixation between the piezoelectric polymer film, and the first detection electrode and the second detection electrode.

In addition, according to this configuration, electrodes which serve as a clue to distinguish between the top and back principal surfaces and the molecular orientation direction are not formed on the piezoelectric polymer film. Even in such a case, by using the shape of the piezoelectric polymer film as a clue, it is possible to distinguish between the top and back principal surfaces of the piezoelectric polymer film and the molecular orientation direction, and increase accuracy in assembling the piezoelectric polymer film in the pressing sensor.

Preferably, the substrate including the first electrode formation portion and the substrate including the second electrode formation portion are formed by a single continuous substrate, and are bent such that the first electrode formation portion and the second electrode formation portion are opposite to each other, and the piezoelectric polymer film is disposed between the first electrode formation portion and the second electrode formation portion.

According to this configuration, it is possible to form the first electrode formation portion and the second electrode formation portion on the same surface of a single substrate, form the first detection electrode and the second detection electrode in the same process, form the first electrode formation portion and the second electrode formation portion in the same process, reduce the number of manufacturing processes and reduce the number of parts.

The present invention relates to a method for manufacturing the above pressing sensor, and the method includes: distinguishing between directions of a top principal surface and a back principal surface of the piezoelectric polymer film based on one planar shape of the piezoelectric polymer film, and adjusting the directions of the top principal surface and the back principal surface of the piezoelectric polymer film to a reference orientation; and disposing the first detection electrode on the top principal surface of the piezoelectric polymer film, and disposing the second detection electrode on the back principal surface of the piezoelectric polymer film.

According to this manufacturing method, it is possible to increase accuracy in correctly assembling the piezoelectric polymer film in the pressing sensor, and accurately manufacture the pressing sensor which can provide a detected voltage of a correct voltage polarity which reflects a direction of a pressing force working on the piezoelectric polymer film.

According to the present invention, the shapes of the top principal surface and the back principal surface of the piezoelectric polymer film differ. Consequently, it is possible to distinguish between the top and back principal surfaces of the piezoelectric polymer film, and increase accuracy in assembling the piezoelectric polymer film in the pressing sensor in the pressing sensor manufacturing process. Consequently, it is possible to prevent (suppress) such a failure that a detected voltage of the pressing sensor is inverted from a predetermined voltage polarity.

### BRIEF EXPLANATION OF THE DRAWINGS

FIGS. 1(A) and 1(B) are a side sectional view and a plan view of a pressing sensor according to a first embodiment of the present invention, and FIG. 1(C) is a side sectional view upon detection of a pressing force.

FIGS. 2(A) and 2(B) are exploded plan views of the pressing sensor according to the first embodiment of the present invention.

FIGS. 3(A) to 3(E) are plan views illustrating a process of manufacturing the pressing sensor according to the first embodiment of the present invention.

FIGS. 4(A) to 4(D) are plan views illustrating an example where a piezoelectric polymer film is assembled.

FIGS. 5(A) and 5(B) are a side sectional view and a plan view of a pressing sensor according to a second embodiment of the present invention, and FIG. 5(C) is a plan view of a piezoelectric polymer film.

FIG. 6 is a plan view illustrating a piezoelectric polymer film according to other embodiments.

### DETAILED DESCRIPTION OF THE INVENTION

A pressing sensor according to the first embodiment of the present invention will be described below.

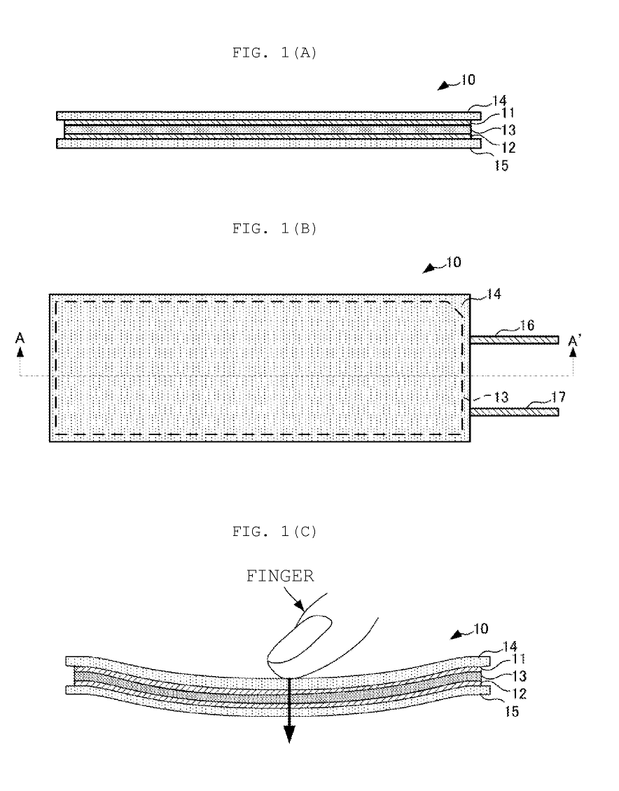

FIG. 1(A) is a side sectional view of a pressing sensor 10 according to the first embodiment of the present invention, and FIG. 1(B) illustrates a cross section passing a position indicated as A-A′.

The pressing sensor 10 includes a first detection electrode 11, a second detection electrode 12, a piezoelectric polymer film 13, a first electrode formation portion 14, a second electrode formation portion 15, a first terminal 16 (not illustrated) and a second terminal 17 (not illustrated).

The first detection electrode 11, the second detection electrode 12, the piezoelectric polymer film 13, the first electrode formation portion 14 and the second electrode formation portion 15 each include a top principal surface and a back principal surface which have flat film shapes and are opposite to each other in a thickness direction. An upper side surface in FIG. 1(A) will be referred to as the top principal surface, and a lower side surface will be referred to as a back principal surface.

The first electrode formation portion 14, the first detection electrode 11, the piezoelectric polymer film 13, the second detection electrode 12 and the second electrode formation portion 15 are disposed in this order from the top principal surface side to the back principal surface side, and are laminated in the thickness direction of the pressing sensor 10. More specifically, the first detection electrode 11 is laminated on the top principal surface of the piezoelectric polymer film 13, and the first electrode formation portion 14 is further laminated on the top principal surface of the first detection electrode 11. Further, the second detection electrode 12 is laminated on the back principal surface of the piezoelectric polymer film 13, and the second electrode formation portion 15 is further laminated on the back principal surface of the second detection electrode 12.

FIG. 1(B) is a plan view illustrating the pressing sensor 10 according to the first embodiment of the present invention seen from the top principal surface side. The first detection electrode 11 (not illustrated), the second detection electrode 12 (not illustrated), the piezoelectric polymer film 13, the first electrode formation portion 14 and the second electrode formation portion 15 (not illustrated) each have an approximately rectangular outer shape in planar view. In this regard, the outer shapes of the first electrode formation portion 14 and the second electrode formation portion 15 (not illustrated) are slightly larger than the outer shape of the piezoelectric polymer film 13.

The first terminal 16 has one end which is inserted between the first electrode formation portion 14 and the piezoelectric polymer film 13 and is physically and electrically connected to the first detection electrode 11, and the other end which is extended to an outside from between the first electrode formation portion 14 and the piezoelectric polymer film 13. The second terminal 17 has one end which is inserted between the second electrode formation portion 15 and the piezoelectric polymer film 13 and is physically and electrically connected to the second detection electrode 12, and the other end which is extended to an outside from between the second electrode formation portion 15 and the piezoelectric polymer film 13.

FIG. 1(C) is a side sectional view of the pressing sensor 10 according to the first embodiment of the present invention upon detection of a pressing force. The pressing sensor 10 is attached to a touch panel which is not illustrated, and is used. The pressing sensor 10 is pushed in the thickness direction from one principal surface side (the top principal surface side of the piezoelectric polymer film 13). Thus, the piezoelectric polymer film 13 produces electric charges. Thus, a detected voltage whose voltage value corresponds to a magnitude of the pressing force (a stretching amount of the piezoelectric polymer film 13) and whose voltage polarity corresponds to a direction of the pressing force is produced between the first detection electrode 11 and the second detection electrode 12.

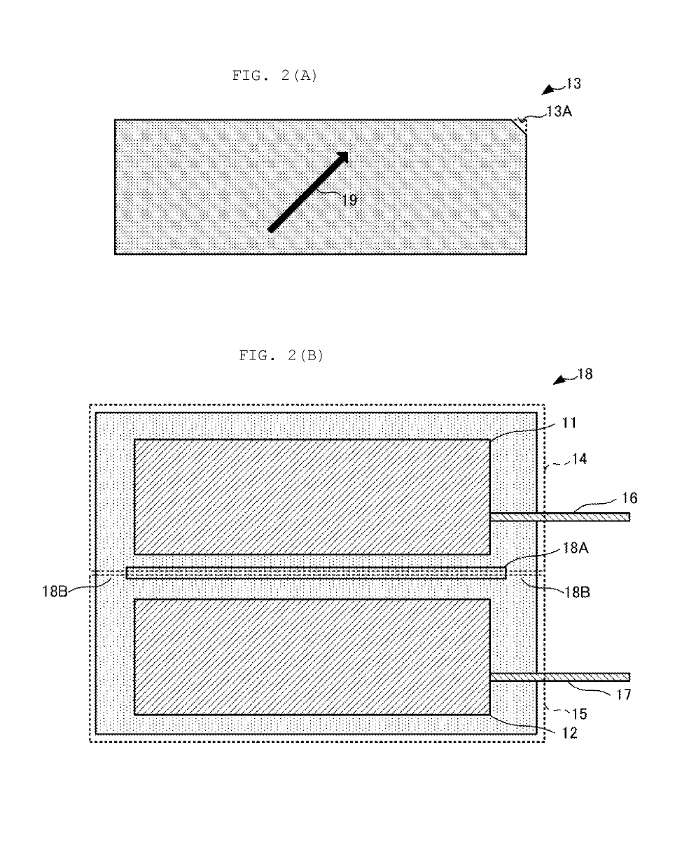

FIG. 2(A) is a plan view illustrating the piezoelectric polymer film 13 seen from the top principal surface side.

The top principal surface and the back principal surface (not illustrated) of the piezoelectric polymer film 13 each have an approximately rectangular shape which includes two long sides which are parallel to each other, and two short sides which are orthogonal to the two long sides. The piezoelectric polymer film 13 has a molecular orientation of a direction 19 which forms about 45° with respect to the long sides and the short sides. A deformed portion 13A is formed at an angular portion which is one of four angular portions formed by the long sides and the short sides and which is provided in the direction 19 from a center portion in planar view. The deformed portion 13A has a cutaway shape which is diagonally cut away from the long sides and the short sides. This piezoelectric polymer film 13 has an approximately rectangular shape and has the deformed portion 13A at the angular portion and thus the shape seen from the top principal surface side and the shape seen from the back principal surface side differ. Consequently, it is possible to distinguish between the top principal surface and the back principal surface. Further, since only one deformed portion 13A is provided at the angular portion, it is possible to distinguish between directionalities in planes of the top principal surface and the back principal surface.

The angular portion of the piezoelectric polymer film 13 at which the deformed portion 13A is formed is not limited to the angular portion in the direction 19 from the center portion in planar view, and may be another angular portion. Further, the number of deformed portions 13A is not limited to one and may be three when the deformed portions 13A are provided at the angular portions of the piezoelectric polymer film 13. Furthermore, the shape of the deformed portion 13A is not limited to a cutaway shape which is diagonally cut away from the long side and the short side, and may have another planar shape.

FIG. 2(B) is a plan view of members which compose the first electrode formation portion 14 and the second electrode formation portion 15.

The first electrode formation portion 14 and the second electrode formation portion 15 are integrally formed by a single electrode formation film 18. The electrode formation film 18 has a rectangular or square outer shape in planar view, and has a slit 18A in the center. The slit 18A is provided at a position which partitions the first electrode formation portion 14 and the second electrode formation portion 15 on the electrode formation film 18, and is elongated in parallel to two parallel sides (the long sides of the first electrode formation portion 14 and the second electrode formation portion 15) of the electrode formation film 18. Join portions 18B are provided on both sides of the slit 18A in the direction in which the slit 18A is elongated in the electrode formation film 18. The join portions 18B join the first electrode formation portion 14 and the second electrode formation portion 15. The slit 18A and the join portions 18B may not necessarily be provided, and may have other shapes.

For the electrode formation film 18, one of PET (polyethylene terephthalate), PEN (polyethylene naphthalate), polyester and PPS (polyphenylene sulfide) is preferably used. By using these materials, it is possible to form the electrode formation film 18, i.e., the first electrode formation portion 14 and the second electrode formation portion 15 as a film having flexibility and translucency.

On one of the principal surfaces of the electrode formation film 18, the first detection electrode 11 and the second detection electrode 12 are formed. More specifically, the first detection electrode 11 is formed in an area which is the first electrode formation portion 14 on the one principal surface of the electrode formation film 18, and the second detection electrode 12 is formed in an area which is the second electrode formation portion 15. The first detection electrode 11 and the second detection electrode 12 may be formed on the piezoelectric polymer film 13 instead of the electrode formation film 18. Further, the first detection electrode 11 and the second detection electrode 12 may be formed separately from the electrode formation film 18 or the piezoelectric polymer film 13.

For the first detection electrode 11 and the second detection electrode 12, one of organic electrodes whose main components are ITO, ZnO and polythiophene, organic electrodes whose main component is polyaniline, silver nanowire electrodes, and carbon nanotube electrodes is preferably used. By using these materials, it is possible to form an electrode pattern having high translucency. In addition, when translucency is not necessary, it is also possible to use electrodes made of a silver paste or metal electrodes formed by deposition, sputtering or plating. Since the pressing sensor 10 is significantly displaced, the first detection electrode 11 and the second detection electrode 12 are particularly preferably organic electrodes whose main component is polythiophene having excellent flexibility, organic electrodes whose main component is polyaniline, silver nanowire electrodes, carbon nanotube electrodes or metal electrodes.

The piezoelectric polymer film 13 illustrated in FIG. 2(A) will be described in more detail. The piezoelectric polymer film 13 is a film whose main material is poly-L-lactic acid (PLLA). PLLA is a chiral polymer whose main chain has a spiral structure, and has a property of exhibiting piezoelectricity by being oriented in a predetermined axial direction. This piezoelectricity is expressed as a piezoelectric tensor component d₁₄ when a film thickness direction is a first axis and a direction in which PLLA molecules are oriented is a third axis. In the piezoelectric polymer film 13 having this piezoelectric tensor component d₁₄, if the PLLA molecules are oriented in a direction which intersects the long sides and the short sides in the top principal surface and the back principal surface, more specifically, in a direction of about 45° with respect to the long sides and the short sides, it is possible to detect a pressing force in the thickness direction. Hence, in the piezoelectric polymer film 13, the direction 19 in which the PLLA molecules are oriented and a formation position of the deformed portion 13A are set such that the direction 19 is oriented toward the angular portion provided with the deformed portion 13A.

In this regard, an angle of the direction 19 in the piezoelectric polymer film 13 is not limited to exact 45° with respect to the long sides and the short sides, and may be any angle close to 45°. When the angle of the direction 19 is closer to 45° with respect to the long sides and the short sides, it is possible to accurately detect a pressing force in the thickness direction. Hence, “approximately 45°” according to the present invention refers to, for example, an angle of a predetermined range around 45° which is about 45°±10°. These specific angles should be appropriately determined according to an entire design based on usage of a displacement sensor or characteristics of each unit.

The piezoelectric polymer film 13 is not limited to a film whose main material is PLLA, and may be a film whose main material is poly-D-lactic acid (PDLA) or poly vinylidene difluoride (PVDF). In this regard, the piezoelectricity of the piezoelectric polymer film 13 whose main material is a chiral polymer such as PLLA or PDLA is exhibited not by ion polarization as in ferroelectrics such as PVDF or PZT, but derives from a spiral structure which is a characteristic structure of molecules. Hence, the chiral polymers do not need to be rendered piezoelectric by poling treatment unlike other polymers such as PVDF or a piezoelectric ceramic for which a piezoelectric crystal thin film is used. Further, although PVDF fluctuates in piezoelectric constant with time and the piezoelectric constant is significantly lowered in some cases, a piezoelectric constant of the chiral polymer is very stable over time.

Further, the chiral polymers do not exhibit pyroelectricity unlike other ferroelectric piezoelectric bodies. Hence, the piezoelectric polymer film 13 whose main material is a chiral polymer can provide a detected voltage corresponding only to a pressing force without depending on a temperature of a detection position upon detection of a press. Further, the chiral polymers are polymers and have flexibility, and therefore are not damaged by significant displacement unlike a piezoelectric ceramic. Consequently, the piezoelectric polymer film 13 whose main material is the chiral polymer can reliably detect a displacement amount without being damaged even when a displacement amount is large.

Further, a relative permittivity of PLLA is about 2.5 and very low, and therefore, when d is a piezoelectric constant and ε^{T} is a dielectric constant, a piezoelectric output constant (=piezoelectric g constant, g=d/ε^{T}) takes a large value. In this regard, the piezoelectric g constant of PVDF whose dielectric constant is ε₃₃^{T}=13×ε₀ and whose piezoelectric tensor component is d₃₁=25 pC/N is g₃₁=0.2172 Vm/N according to the above equation. Meanwhile, the piezoelectric g constant of PLLA whose piezoelectric tensor component d₁₄=10 pC/N is converted into g₃₁ and is calculated as d₁₄=2×d₃₁ and therefore d₃₁=5 pC/N holds and g₃₁=0.2258 Vm/N holds. Consequently, by using PLLA whose piezoelectric tensor component is d₁₄=10 pC/N, it is possible to obtain sufficient sensor sensitivity as in the case of PVDF. Further, the inventors of the present invention experimentally obtained PLLA of d₁₄=15 to 20 pC/N, and it is possible to compose the pressing sensor 10 with a very high sensitivity by using the PLLA film.

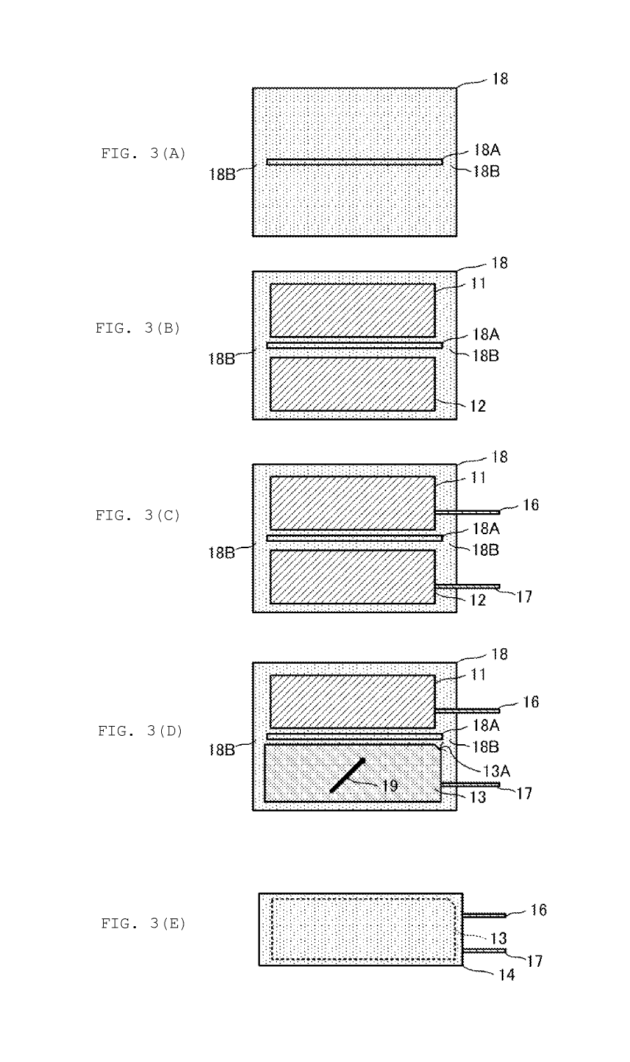

Next, an example of manufacturing the pressing sensor 10 will be described. FIGS. 3(A) to 3(E) are plan views illustrating states in a process of manufacturing the pressing sensor 10.

In the process of manufacturing the pressing sensor 10, as illustrated in FIG. 3(A), the slit 18A and the join portions 18B are first provided to form the electrode formation film 18.

Next, as illustrated in FIG. 3(B), a transparent electrode such as an organic electrode whose main components are ITO, ZnO and polythiophene is formed as a pattern on one principal surface of the electrode formation film 18. Thus, the first detection electrode 11 and the second detection electrode 12 are formed on the electrode formation film 18.

Next, as illustrated in FIG. 3(C), the first detection electrode 11 and the second detection electrode 12 are physically and electrically connected with the first terminal 16 and the second terminal 17, respectively.

Further, a PLLA film is prepared, and the PLLA film is stretched along a predetermined direction. Thus, PLLA molecules are oriented in the PLLA film. Further, the PLLA film in which the PLLA molecules are oriented is cut to define the long sides and the short sides of the piezoelectric polymer film 13 at an angle of approximately 45° with respect to the stretching direction, and the deformed portion 13A is formed on this piezoelectric polymer film 13.

In addition, the PLLA film may be biaxially stretched. In this case, by employing different stretching ratios for respective directions in which the PLLA film is stretched, it is possible to provide the same effect as that of uniaxial stretching. When, for example, a given direction is an X axis and the film is stretched to eight times the film in an X axis direction, and the film is stretched to twice the film in a Y axis direction orthogonal to the X axis, it is possible to provide the same effect in terms of the piezoelectric constant as an effect obtained when the film is subjected to uniaxial stretching to be stretched to four times the film in the X axis direction. Simply uniaxially-stretched film is likely to break in a stretching axial direction. Consequently, by performing biaxial stretching as described above, it is possible to increase the strength to some degree.

Next, as illustrated in FIG. 3(D), the piezoelectric polymer film 13 is assembled on the electrode formation film 18. More specifically, the piezoelectric polymer film 13 is disposed on the second detection electrode 12 (or the first detection electrode 11), and the second detection electrode 12 (or the first detection electrode 11) and the piezoelectric polymer film 13 are joined by a conductive adhesive. The second detection electrode 12 is joined to the piezoelectric polymer film 13 in at least a conductive state.

In this regard, the top and back principal surfaces of the piezoelectric polymer film 13 and the orientation of the direction in which molecules are oriented can be distinguished based on the position and the shape of the deformed portion 13A. Consequently, it is possible to adjust the top and back principal surfaces of the piezoelectric polymer film 13 and a direction of the direction 19 to assembly reference directions and assemble the piezoelectric polymer film 13 on the electrode formation film 18.

Preferably, in this process, the position and the shape of the deformed portion 13A of the piezoelectric polymer film 13 is obtained by using an image determining device or the like, the top and back principal surfaces of the piezoelectric polymer film 13 and the orientation of the direction 19 are distinguished, the top and back principal surfaces of the piezoelectric polymer film 13 and the orientation of the direction 19 are adjusted to orient to the reference directions with use of the image determining device and handling equipment, and then the piezoelectric polymer film 13 is assembled on the electrode formation film 18.

Next, as illustrated in FIG. 3(E), the electrode formation film 18 is folded at a folding portion including the slit 18A and the join portions 18B, and the piezoelectric polymer film 13 is sandwiched between the first electrode formation portion 14 and the second electrode formation portion 15, i.e., between the first detection electrode 11 and the second detection electrode 12. In this regard, the first detection electrode 11 (or the second detection electrode 12) and the piezoelectric polymer film 13 are joined by a conductive adhesive. The first detection electrode 11 is joined to the piezoelectric polymer film 13 in at least a conductive state.

It is possible to manufacture the pressing sensor 10 according to the present embodiment by performing the above process. In the process of assembling the piezoelectric polymer film 13 on the electrode formation film 18, the piezoelectric polymer film 13 is correctly assembled by distinguishing between the top and back principal surfaces of the piezoelectric polymer film 13 and the reference direction based on the position and the shape of the deformed portion 13A of the piezoelectric polymer film 13, i.e., the shape of the top principal surface and the shape of the back principal surface, and adjusting the top and back principal surfaces of the piezoelectric polymer film 13 and the direction 19 to the assembly reference direction. Consequently, it is possible to prevent (suppress) a failure that a voltage polarity of a detected voltage is inverted in the pressing sensor 10, or the piezoelectric polymer film is assembled in a state where the direction 19 of the piezoelectric polymer film is misaligned from the assembly reference direction.

There is also a case where the electrode formation film 18, the first detection electrode 11 and the second detection electrode 12 are transparent, and the top and back principal surfaces of the piezoelectric polymer film 13 and the direction of molecular orientation can be distinguished from an outside of the pressing sensor 10. In such a case, after each of the above processes is performed, a process of distinguishing between the top and back principal surfaces of the piezoelectric polymer film 13 assembled in the pressing sensor 10 and the orientation of the molecular orientation by using an image determining device again, and removing the pressing sensor 10 to which the piezoelectric polymer film 13 has been erroneously assembled may be performed.

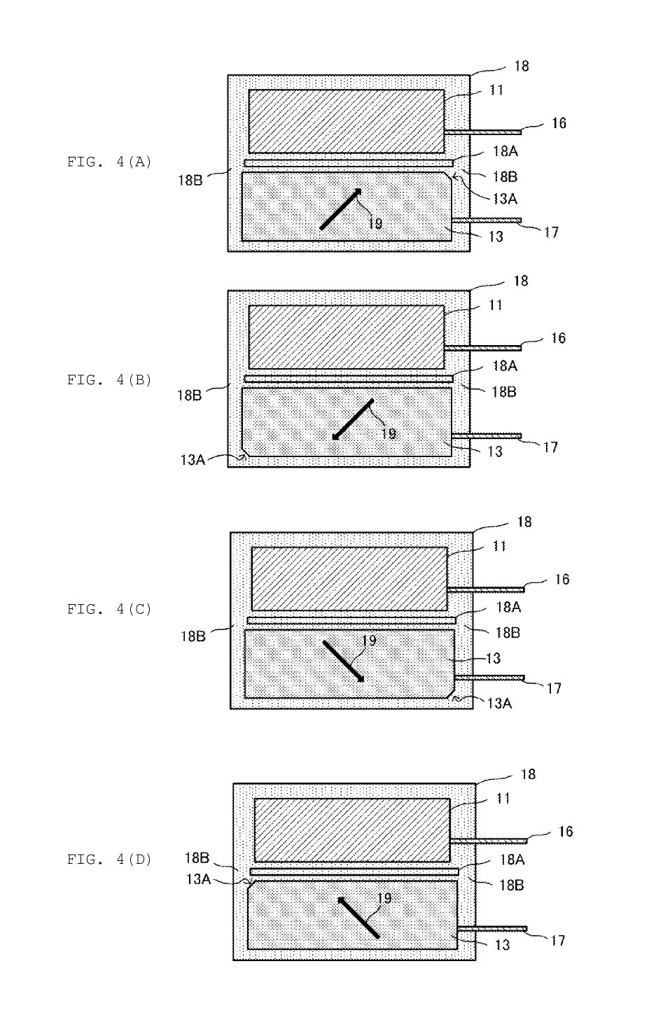

FIGS. 4(A) to 4(D) are plan views illustrating an example where the piezoelectric polymer film 13 is assembled in the pressing sensor 10. The direction of the molecular orientation of the piezoelectric polymer film 13 differs 180° between FIGS. 4(A) and 4(B). The top and back principal surfaces of the piezoelectric polymer film 13 are upside down between in FIGS. 4(A) and 4(B), and 4(C) and 4(D). The direction of the molecular orientation of the piezoelectric polymer film 13 differs 180° between FIGS. 4(C) and 4(D).

As described above, in the process of assembling the piezoelectric polymer film 13 on the electrode formation film 18, if the top and back principal surfaces of the piezoelectric polymer film 13 are assembled upside down, the polarity of an output voltage of the pressing sensor 10 is inverted. However, in the present embodiment, the piezoelectric polymer film 13 has an approximately rectangular shape in planar view, and the deformed portion 13A is formed at one angular portion. Therefore, the shape of the top principal surface of the piezoelectric polymer film 13 and the shape of the back principal surface differ. Consequently, it is possible to assemble the piezoelectric polymer film 13 on the electrode formation film 18 by distinguishing between the top and back principal surfaces of the piezoelectric polymer film 13, and adjusting directions of the top and back principal surfaces of the piezoelectric polymer film 13 to the assembly reference direction.

When, for example, the position of the deformed portion 13A is on a diagonal line rising rightward (falling leftward) of the piezoelectric polymer film 13 as illustrated in FIGS. 4(A) and 4(B), the top principal surface is directed to the front in this piezoelectric polymer film 13. By contrast with this, when the position of the deformed portion 13A is on a diagonal line falling rightward (rising leftward) of the piezoelectric polymer film 13 as illustrated in FIGS. 4(C) and 4(D), the back principal surface is directed to the front in this piezoelectric polymer film 13.

Consequently, when the back principal surface of the piezoelectric polymer film 13 is attached to the second detection electrode in a state where the top principal surface of the piezoelectric polymer film 13 is directed to the front in this pressing sensor 10 as illustrated in FIGS. 4(A) and 4(B), the piezoelectric polymer film 13 is correctly assembled in the electrode formation film 18. Further, a voltage polarity of a detected voltage outputted from the pressing sensor 10 to which the piezoelectric polymer film 13 has been assembled as described above satisfies a specification which complies with requirement of the pressing sensor 10.

Further, when the top principal surface of the piezoelectric polymer film 13 is attached to the second detection electrode in a state where the back principal surface of the piezoelectric polymer film 13 is directed to the front in this pressing sensor 10 as illustrated in FIGS. 4(C) and 4(D), the piezoelectric polymer film 13 is erroneously assembled upside down on the electrode formation film 18. Further, a voltage polarity of a detected voltage outputted from the pressing sensor 10 to which the piezoelectric polymer film 13 has been assembled as described above is inverted, and does not comply with the requirement of the pressing sensor 10 and does not satisfy a specification.

As described above, in the pressing sensor 10 according to the present embodiment, the shape of the top principal surface of the piezoelectric polymer film 13 assembled in the pressing sensor 10 and the shape of the back principal surface differ. Consequently, it is possible to distinguish between the top and back principal surfaces of the piezoelectric polymer film 13, correctly assemble the top and back principal surfaces of the piezoelectric polymer film 13 when the piezoelectric polymer film 13 is assembled in the pressing sensor 10, and prevent the voltage polarity of the detected voltage from being inverted in the pressing sensor 10.

In the present embodiment, the first electrode formation portion 14 and the second electrode formation portion 15 are formed on one electrode formation film 18. However, the first electrode formation portion 14 and the second electrode formation portion 15 may be separately formed. Further, the first detection electrode 11 and the second detection electrode 12 may be directly formed on the piezoelectric polymer film 13 instead of being formed on the first electrode formation portion 14 and the second electrode formation portion 15.

Further, in the present embodiment, the piezoelectric polymer film 13 has an approximately rectangular shape. Consequently, even if the piezoelectric polymer film 13 is assembled in a state where the direction of the direction 19 is not correct, the direction of the direction 19 simply becomes opposite and the pressing sensor 10 can be used. However, when the piezoelectric polymer film has a square shape or a circular shape, the direction of the direction 19 of the piezoelectric polymer film is misaligned from the assembly reference direction in some cases. This misalignment causes deterioration of characteristics of the pressing sensor. Hence, the direction of the direction 19 of the piezoelectric polymer film is desirably adjusted to the assembly reference direction.

Next, a pressing sensor according to the second embodiment of the present invention will be described.

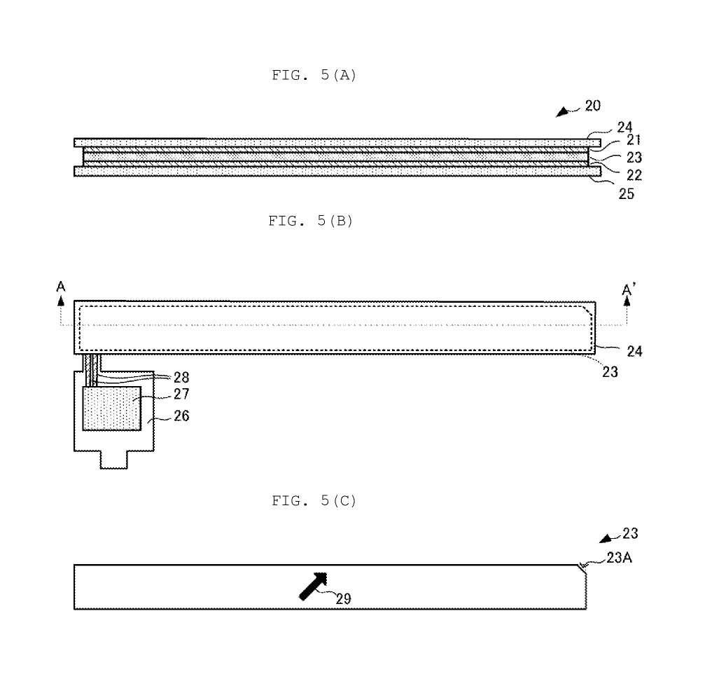

FIG. 5(A) is a side sectional view of a pressing sensor 20 according to the second embodiment of the present invention, and FIG. 5(B) illustrates a cross section passing a position indicated as A-A′.

The pressing sensor 20 includes a first detection electrode 21, a second detection electrode 22, a piezoelectric polymer film 23, a first electrode formation portion 24, a second electrode formation portion 25, a part mounting portion 26 (not illustrated) and a circuit part 27 (not illustrated).

The first detection electrode 21, the second detection electrode 22, the piezoelectric polymer film 23, the first electrode formation portion 24 and the second electrode formation portion 25 each include a top principal surface and a back principal surface which have flat film shapes and are opposite to each other in a thickness direction. In the following description, an upper side surface of each portion in FIG. 5(A) will be referred to as the top principal surface, and a lower side surface will be referred to as a back principal surface.

The first electrode formation portion 24, the first detection electrode 21, the piezoelectric polymer film 23, the second detection electrode 22 and the second electrode formation portion 25 are disposed in this order from the top principal surface side to the back principal surface side, and are laminated in the thickness direction of the pressing sensor 20. More specifically, the first detection electrode 21 is laminated on the top principal surface of the piezoelectric polymer film 23, and the first electrode formation portion 24 is further laminated on the top principal surface of the first detection electrode 21. Further, the second detection electrode 22 is laminated on the back principal surface of the piezoelectric polymer film 23, and the second electrode formation portion 25 is further laminated on the back principal surface of the second detection electrode 22. In addition, similarly to the first embodiment, the first electrode formation portion 24 and the second electrode formation portion 25 are formed by an integrated electrode formation film.

FIG. 5(B) is a plan view illustrating the pressing sensor 20 according to the second embodiment of the present invention seen from the top principal surface side. The first detection electrode 21 (not illustrated), the second detection electrode 22 (not illustrated), the piezoelectric polymer film 23, the first electrode formation portion 24 and the second electrode formation portion 25 (not illustrated) each have an approximately rectangular outer shape in planar view.

Further, the part mounting portion 26 and the second electrode formation portion 25 (not illustrated) are integrally formed, and are provided to protrude in a direction along the short side from one long side of the second electrode formation portion 25 (not illustrated). On the top principal surface of the part mounting portion 26, wiring conductors 28 are extended from the first detection electrode 21 (not illustrated) and the second detection electrode 22 (not illustrated). Further, pad conductors which are not illustrated and connected with the wiring conductors 28 are provided. The circuit part 27 is mounted on the top principal surface of the part mounting portion 26, and is connected to the first detection electrode 21 (not illustrated) and the second detection electrode 22 (not illustrated) through the pad conductors and the wiring conductors 28.

FIG. 5(C) is a plan view illustrating the piezoelectric polymer film 23 seen from the top principal surface side.

The top principal surface and the back principal surface (not illustrated) of the piezoelectric polymer film 23 each have an approximately rectangular shape which includes two long sides which are parallel to each other, and two short sides which are orthogonal to the two long sides. The piezoelectric polymer film 23 also has an orientation of a direction 29 which forms about 45° with respect to each side. A deformed portion 23A is formed at an angular portion which is one of four angular portions formed by the long sides and the short sides and which is provided in the direction 29 from a center portion in planar view. The deformed portion 23A has a cutaway shape which is diagonally cut away from the long sides and the short sides. This piezoelectric polymer film 23 also has an approximately rectangular shape and has the deformed portion 23A at the angular portion and thus the shape of the top principal surface and the shape of the back principal surface side differ. Consequently, it is possible to distinguish between the top principal surface and the back principal surface. Further, since only one deformed portion 23A is provided at the angular portion, it is possible to distinguish between directionalities in planes of the top principal surface and the back principal surface.

As described above, in the pressing sensor 20 according to the present embodiment, too, the top principal surface of the piezoelectric polymer film 23 assembled in the pressing sensor 20 and the back principal surface differ. Consequently, it is possible to distinguish between the top and back principal surfaces of the piezoelectric polymer film 23, and correctly assemble the top and back principal surfaces of the piezoelectric polymer film 23 when the piezoelectric polymer film 23 is assembled in the pressing sensor 20. Consequently, it is possible to prevent (suppress) that the voltage polarity of the detected voltage is inverted in the pressing sensor 20.

In this regard, since the pressing sensor 20 is formed by mounting the circuit part 27 on the electrode formation film, low heat resistance of the piezoelectric polymer film 23 may become a concern in the method for manufacturing the pressing sensor 20. More specifically, according to the method for manufacturing the pressing sensor 20, if the circuit part 27 is mounted on the part mounting portion 26 by a method including heating using reflow after the piezoelectric polymer film 23 is assembled, characteristics of the piezoelectric polymer film 23 may deteriorate due to heat.

Hence, in the process of manufacturing the pressing sensor 20, it is necessary to assemble the piezoelectric polymer film 23 after the circuit part 27 is mounted on the surface of the part mounting portion 26 by the method including heating using reflow. Then, if top and back principal surfaces of the piezoelectric polymer film 23 are erroneously attached to the electrode formation film on which the circuit part 27 is mounted on the surface, it is necessary to discard the expensive circuit part 27, and waste loss increases. Hence, the present invention which can increase accuracy in assembling the piezoelectric polymer film 23 is particularly effective in the second embodiment where the circuit part is mounted on the surface of the electrode formation film.

In the present embodiment, the first electrode formation portion 24 and the second electrode formation portion 25 are formed on one electrode formation film. However, the first electrode formation portion 24 and the second electrode formation portion 25 may be separately formed. Further, the first detection electrode 21 and the second detection electrode 22 may be directly formed on the piezoelectric polymer film 23 instead of being formed on the first electrode formation portion 24 and the second electrode formation portion 25.

Next, other embodiments of a piezoelectric polymer film assembled in a pressing sensor will be described.

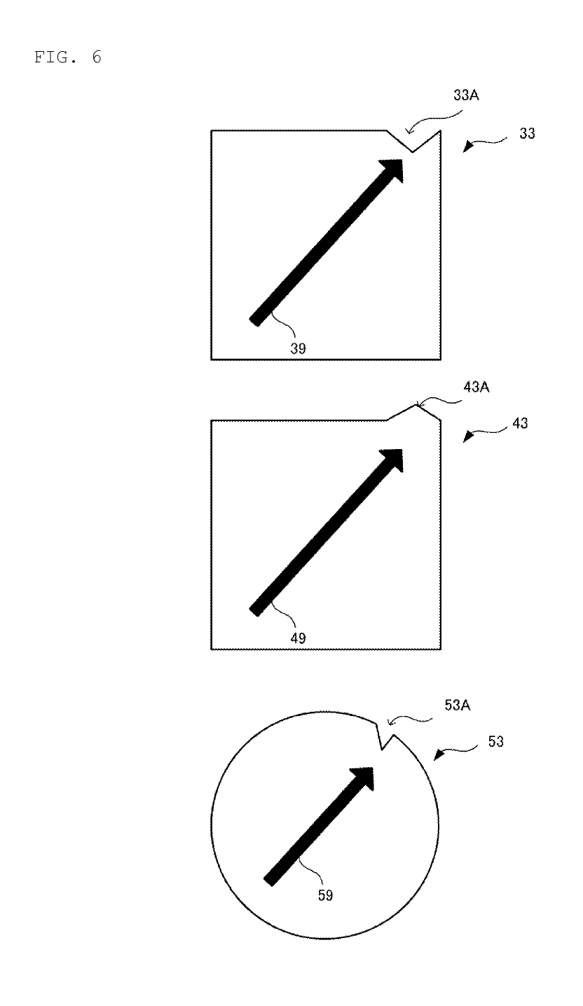

FIG. 6(A) is a plan view illustrating a piezoelectric polymer film 33 seen from the top principal surface side.

The top principal surface and the back principal surface (not illustrated) of the piezoelectric polymer film 33 each have an approximately square shape which includes four sides which are orthogonal to each other. Further, the piezoelectric polymer film 33 has an orientation of a direction 39 which forms about 45° with respect to each side, and a deformed portion 33A which has been cut away in a triangular shape is formed at a position offset from the center of one side of the four sides. Consequently, shapes of the top principal surface and the back principal surface of this piezoelectric polymer film 33 differ. Consequently, it is possible to distinguish between the top principal surface and the back principal surface. Further, since only one deformed portion 33A is provided at the position offset from the center of one side, it is possible to distinguish between directionalities in planes in the top principal surface and the back principal surface of the piezoelectric polymer film 33.

There is a concern that, when the piezoelectric polymer film 33 having such an approximately square shape is assembled in a pressing sensor, a direction of the direction 39 of the piezoelectric polymer film 33 is misaligned 90° or 180° from an assembly reference direction. However, it is possible to distinguish between directionalities in planes of the top principal surface and the back principal surface of the piezoelectric polymer film 33 based on the deformed portion 33A. Consequently, it is possible to easily adjust the direction of the direction 39 to the assembly reference direction, and prevent (suppress) that deterioration of characteristics of the pressing sensor is caused by misalignment of the direction 39.

FIG. 6(B) is a plan view illustrating a piezoelectric polymer film 43 seen from the top principal surface side.

The top principal surface and the back principal surface (not illustrated) of the piezoelectric polymer film 43 each have an approximately square shape which includes four sides which are orthogonal to each other. Further, the piezoelectric polymer film 43 has an orientation of a direction 49 which forms about 45° with respect to each side, and a deformed portion 43A which protrudes in a triangular shape is formed at a position offset from the center of one side of the four sides. Consequently, shapes of the top principal surface and the back principal surface of this piezoelectric polymer film 43 also differ. Consequently, it is possible to distinguish between the top principal surface and the back principal surface. Further, since only one deformed portion 43A is provided at the position offset from the center of one side, it is possible to distinguish between directionalities in planes in the top principal surface and the back principal surface of the piezoelectric polymer film 43.

There is a concern that, when the piezoelectric polymer film 43 having such an approximately square shape is assembled in a pressing sensor, too, a direction of the direction 49 of the piezoelectric polymer film 43 is misaligned 90° or 180° from an assembly reference direction. However, it is possible to distinguish between directionalities in the planes of the top principal surface and the back principal surface of the piezoelectric polymer film 43 based on the deformed portion 43A. Consequently, it is possible to easily adjust the direction of a uniaxial direction to the assembly reference direction, and prevent (suppress) that deterioration of characteristics of the pressing sensor is caused by misalignment of the direction 49.

FIG. 6(C) is a plan view illustrating a piezoelectric polymer film 53 seen from the top principal surface side.

The top principal surface and the back principal surface (not illustrated) of the piezoelectric polymer film 53 each have an approximately circular shape and has an orientation of a direction 59. The piezoelectric polymer film 53 has a deformed portion 53A which is cut away in an approximately right-angled triangular shape and is formed at a position of the direction 59 from a center portion in planar view. This piezoelectric polymer film 53 has the deformed portion 53A which is cut away in the approximately right-angled triangular shape. Consequently, shapes of the top principal surface and the back principal surface differ, and it is possible to distinguish between the top principal surface and the back principal surface. Further, since the deformed portion 53A is provided in the approximately right-angled triangular shape, it is possible to distinguish between directionalities in planes of the top principal surface and the back principal surface of the piezoelectric polymer film 53.

There is a concern that, when the piezoelectric polymer film 53 having such an approximately circular shape is assembled in a pressing sensor, a direction of the direction 59 of the piezoelectric polymer film 53 is misaligned at any angle (such as 45° or 90°) from an assembly reference direction. However, it is possible to distinguish between directionalities in the planes of the top principal surface and the back principal surface of the piezoelectric polymer film 53 based on the deformed portion 53A. Consequently, it is possible to easily adjust the direction of the direction 59 to the assembly reference direction, and prevent (suppress) that deterioration of characteristics of the pressing sensor is caused by misalignment of the direction 59.

As described above, the piezoelectric polymer film can be formed in various planar shapes. Entire planar shapes of the piezoelectric polymer film are not limited to a rectangular shape, a square shape and a circular shape, and may be polygonal shapes such as a trapezoidal shape, a parallelogram shape and a quadrangular shape and other planar shapes such as an elliptical shape and an oval shape.

Further, a deformed portion provided on a piezoelectric polymer film is not limited to a cutaway shape which is cut away from an outer circumference to an inside, and may have a protrusion shape which protrudes from the outer circumference to the outside or an opening shape which is provided closer to the inside than the outer circumference. Furthermore, the planar shape of the deformed portion is not limited to the triangular shape and may be other planar shapes such as a quadrangular shape, a circular shape and a semi-circular shape. Still further, a position at which the deformed portion is provided on the piezoelectric polymer film may also be any portion which makes it possible to recognize the directionalities.

### DESCRIPTION OF REFERENCE SYMBOLS

10, 20 PRESSING SENSOR

11, 21 FIRST DETECTION ELECTRODE

12, 22 SECOND DETECTION ELECTRODE

13, 23, 33, 43, 53 PIEZOELECTRIC POLYMER FILM

13A, 23A, 33A, 43A, 53A DEFORMED PORTION

14, 24 FIRST ELECTRODE FORMATION PORTION

15, 25 SECOND ELECTRODE FORMATION PORTION

16 FIRST TERMINAL

17 SECOND TERMINAL

18 ELECTRODE FORMATION FILM

18A SLIT

18B join portion

19, 29, 39, 49, 59 DIRECTION

26 PART MOUNTING PORTION

27 CIRCUIT PART

28 WIRING CONDUCTOR

1. A pressing sensor comprising:
a piezoelectric polymer film which includes a top principal surface and a back principal surface opposite to each other, and a piezoelectric polymer within the film is oriented along the top principal surface and the back principal surface;
a first detection electrode opposing the top principal surface of the piezoelectric polymer film; and
a second detection electrode opposing the back principal surface of the piezoelectric polymer film and positioned opposite to the first detection electrode,
wherein a first shape of the piezoelectric polymer film as viewed from the top principal surface and a second shape of the piezoelectric polymer film as viewed from the back principal surface differ from each other.

2. The pressing sensor according to claim 1, wherein the piezoelectric polymer film includes a deformed portion having one of a cutaway shape, a projection shape and an opening shape exposed on the top principal surface and the back principal surface.

3. The pressing sensor according to claim 2, wherein
the top principal surface and the back principal surface of the piezoelectric polymer film each include two long sides which are parallel to each other, and two short sides which are orthogonal to the two long sides, and
the deformed portion is an angular portion connecting at least one of the two long sides with at least one of the two short sides.

4. The pressing sensor according to claim 2, wherein
the top principal surface and the back principal surface of the piezoelectric polymer film each include four sides which are orthogonal to each other, and
the deformed portion is on one side of the four sides and offset from a center of the one side.

5. The pressing sensor according to claim 2, wherein a first shape of the deformed portion as viewed from the top principal surface of the piezoelectric polymer film and a second shape of the deformed portion as viewed from the back principal surface of the piezoelectric polymer film differ from each other.

6. The pressing sensor according to claim 2, wherein
the piezoelectric polymer film includes four sides which are orthogonal to each other, and
a main material of the piezoelectric polymer film is a chiral polymer which is oriented in a direction that intersects each of the four sides.

7. The pressing sensor according to claim 6, wherein the chiral polymer is oriented in a direction of approximately 45° with respect to each of the four sides.

8. The pressing sensor according to claim 1, further comprising:
a first electrode formation portion opposing the first detection electrode; and
a second electrode formation portion opposing the second detection electrode, wherein the first electrode formation portion and the second electrode formation portion sandwich the piezoelectric polymer film therebetween.

9. The pressing sensor according to claim 8, wherein
the first electrode formation portion and the second electrode formation portion comprise a single continuous substrate that is bent such that the first electrode formation portion and the second electrode formation portion oppose to each other with the piezoelectric polymer film disposed therebetween.

10. A method for manufacturing a pressing sensor, the method comprising:
distinguishing between directions of a top principal surface and a back principal surface of a piezoelectric polymer film based on a planar shape of the piezoelectric polymer film, and adjusting the directions of the top principal surface and the back principal surface of the piezoelectric polymer film to a reference orientation; and
disposing a first detection electrode opposite the top principal surface of the piezoelectric polymer film, and disposing a second detection electrode opposite the back principal surface of the piezoelectric polymer film,
wherein a piezoelectric polymer within the film is oriented along the top principal surface and the back principal surface, and
wherein a first shape of the piezoelectric polymer film as viewed from the top principal surface and a second shape of the piezoelectric polymer film as viewed from the back principal surface differ from each other.

11. The method for manufacturing the pressing sensor according to claim 10, forming a deformed portion having one of a cutaway shape, a projection shape and an opening shape exposed on the top principal surface and the back principal surface in the piezoelectric polymer film.

12. The method for manufacturing the pressing sensor according to claim 11, wherein
the top principal surface and the back principal surface of the piezoelectric polymer film each include two long sides which are parallel to each other, and two short sides which are orthogonal to the two long sides, and
the deformed portion is formed as an angular portion connecting at least one of the two long sides with at least one of the two short sides.

13. The method for manufacturing the pressing sensor according to claim 11, wherein
the top principal surface and the back principal surface of the piezoelectric polymer film each include four sides which are orthogonal to each other, and
the deformed portion is formed on one side of the four sides and offset from a center of the one side.

14. The method for manufacturing the pressing sensor according to claim 11, wherein a first shape of the deformed portion as viewed from the top principal surface of the piezoelectric polymer film and a second shape of the deformed portion as viewed from the back principal surface of the piezoelectric polymer film differ from each other.

15. The method for manufacturing the pressing sensor according to claim 11, wherein
the piezoelectric polymer film includes four sides which are orthogonal to each other, and
a main material of the piezoelectric polymer film is a chiral polymer which is oriented in a direction that intersects each of the four sides.

16. The method for manufacturing the pressing sensor according to claim 15, wherein the chiral polymer is oriented in a direction of approximately 45° with respect to each of the four sides.

17. The method for manufacturing the pressing sensor according to claim 10, further comprising:
disposing a first electrode formation portion so as to oppose the first detection electrode; and
disposing a second electrode formation portion so as to oppose the second detection electrode such that the first electrode formation portion and the second electrode formation portion sandwich the piezoelectric polymer film therebetween.

18. The method for manufacturing the pressing sensor according to claim 17, wherein
the first electrode formation portion and the second electrode formation portion comprise a single continuous substrate, and
bending the single continuous substrate such that the first electrode formation portion and the second electrode formation portion oppose to each other with the piezoelectric polymer film disposed therebetween.
